(19) United States
(12) Patent Application Publication
(10) Pub. No.: US 2024/0112953 A1
(43) Pub. Date: Apr. 4, 2024

(54) METAL FILL STRUCTURES FOR ISOLATORS TO MEET METAL DENSITY AND HIGH VOLTAGE ELECTRIC FIELD REQUIREMENTS

(71) Applicant: Texas Instruments Incorporated, Dallas, TX (US)

(72) Inventors: Jeffrey Alan West, Dallas, TX (US); Elizabeth Costner Stewart, Dallas, TX (US); Thomas Dyer Bonifield, Dallas, TX (US); Byron Lovell Williams, Plano, TX (US); Kashyap Barot, Bangalore (IN); Viresh Chinchansure, Bangalore (IN); Sreeram N S, Bangalore (IN)

(21) Appl. No.: 18/148,231

(22) Filed: Dec. 29, 2022

Related U.S. Application Data
(60) Provisional application No. 63/411,952, filed on Sep. 30, 2022.

(51) Int. Cl. H01L 21/768; H01L 23/522; H01L 23/528

(52) U.S. Cl. CPC H01L 21/76877; H01L 21/76816; H01L 23/5226; H01L 23/528

(57) ABSTRACT

A microelectronic device including a galvanic isolator with filler metal within an upper isolation element. The galvanic isolator includes a lower isolation element, an upper isolation element, and an inorganic dielectric plateau between the lower isolation element and the upper isolation element. The upper isolation element contains tines of filler metal which are electrically tied to each other and are electrically tied to the upper isolation element. The ends of the tines are rounded to minimize electric fields. The filler metal increases the overall metal density on the metal layer of the upper isolation element to meet the typical metal density requirements of modern microelectronic fabrication processing.

### CROSS REFERENCE TO RELATED APPLICATIONS

This application claims the benefit of U.S. Provisional Patent Application No. 63/411,952 (Texas Instruments Docket No. T100209US01), filed on 30 Sep. 2022 and hereby incorporated herein by reference in its entirety.

### FIELD

This disclosure relates to the field of microelectronic devices. More particularly, but not exclusively, this disclosure relates to microelectronic devices with metal fill structures.

### BACKGROUND

Galvanic isolation is a principle of isolating functional sections of electrical systems to prevent current flow while energy or information can still be exchanged between sections by other means, such as capacitance, induction, electromagnetic waves, optical, acoustic, or mechanical means. Galvanic isolation is typically used where two or more electric circuits communicate, but their grounds or reference nodes may be at different potentials. It is an effective method of breaking ground loops by preventing unwanted current from flowing between two units sharing a reference conductor. Galvanic isolation is also used for safety as a means of preventing accidental current from reaching ground through a person's body.

Isolators are devices designed to minimize direct current and unwanted transient currents between two systems or circuits while allowing data and power transmission between the two. In most applications, isolators also act as a barrier to high voltage in addition to allowing the system to function properly. New methods to form isolator features which are electrically functional are needed.

### SUMMARY

The following presents a simplified summary in order to provide a basic understanding of one or more aspects of the present patent disclosure. The summary is not an extensive overview of the disclosure and is not intended to identify key or critical elements of the disclosure, nor is it to delineate the scope thereof. Rather, the primary purpose of the summary is to present some concepts of the disclosure in a simplified form as a prelude to a more detailed description that is present later.

Embodiments of a microelectronic device including a galvanic isolation device hereafter referred to as the isolation device are disclosed. The isolation device includes a lower isolation element hereafter referred to as the lower metal coil, an upper isolation element hereafter referred to as the upper metal coil, and a reinforced galvanic isolation device inorganic dielectric stack hereafter referred to as the plateau between the lower metal coil and the upper metal coil. The upper coil of the isolator contains metal tines of filler metal which are in electrical contact with each other and are in electrical contact to the upper metal coil of the isolator. The ends of the metal tines are rounded to minimize electric fields. The filler metal increases the overall metal density on the metal layer of the upper coil to meet the typical metal density requirements of modern microelectronic fabrication processing.

### BRIEF DESCRIPTION OF THE VIEWS OF THE DRAWINGS

Embodiments of the present disclosure are illustrated by way of example, and not by way of limitation, in the Figures of the accompanying drawings in which like references indicate similar elements. It should be noted that different references to “an” or “one” embodiment in this disclosure are not necessarily to the same embodiment, and such references may mean at least one. Further, when a particular feature, structure, or characteristic is described in connection with an embodiment, it is submitted that it is within the knowledge of one skilled in the art to affect such feature, structure, or characteristic in connection with other embodiments whether or not explicitly described.

The accompanying drawings are incorporated into and form a part of the specification to illustrate one or more exemplary embodiments of the present disclosure. Various advantages and features of the disclosure will be understood from the following detailed description taken in connection with the appended claims and with reference to the attached drawing Figures in which:

FIG. 1A is a cross sectional view of an example microelectronic device including a galvanic isolator including a filler metal layer electrically connected to the upper metal coil.

FIG. 1B is a top-down view showing a filler metal layer electrically connected to an upper metal coil in relationship to the upper metal coil of the microelectronic device shown in FIG. 1A.

FIG. 1C is a perspective view showing a filler metal layer electrically connected to an upper metal coil in relationship to the upper metal coil of the microelectronic device shown in FIG. 1A.

FIG. 1D is a detailed view of the termination region of a metal tine of a filler metal layer with a semicircular termination.

FIG. 1E is a detailed view of the termination region of a metal tine of a filler metal layer with an elliptical termination.

FIG. 1F is a detailed view of the termination region of a metal tine of a filler metal layer with a termination consisting of rounded corners.

FIG. 1G is a detailed view of an interior termination region of a metal tine of a filler metal layer which is semicircular.

FIG. 1H is a detailed view of an interior termination region of a metal tine of a filler metal layer which is elliptical.

FIG. 1I is a detailed view of an interior termination region of a metal tine of a filler metal layer which consists of rounded corners.

### DETAILED DESCRIPTION

The following co-pending patent applications have related subject matter and are hereby incorporated by reference: U.S. patent application Ser. No. 17/957,847 (Texas Instruments docket number T102472US01, titled “GALVANIC ISOLATION DEVICE”, by West, et al.), Filed Sep. 30, 2022, and U.S. patent application Ser. No. 17/958,040 (Texas Instruments docket number T92886US01, titled “SINGLE DIE REINFORCED GALVANIC ISOLATION DEVICE”, by West, et al.), Filed Sep. 30, 2022. With their mention in this section, these patent applications are not admitted to be prior art with respect to the present invention.

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

Example microelectronic devices described below may include or be formed of a semiconductor material like Silicon (Si), Silicon Carbide (SiC), Silicon Germanium (SiGe), Gallium Arsenide (GaAs) or an organic semiconductor material. The semiconductor material may be embodied as a semiconductor wafer. The microelectronic devices include one or more galvanic isolation devices. The microelectronic devices may also include one or more semiconductor component or components such as metal oxide semiconductor field effect transistors (MOSFETs), insulated gate bipolar transistors (IGBTs) gate drivers, input/output, and control circuitry, as well as microprocessors, microcontrollers, and/or micro-electro-mechanical components or systems (MEMS). The microelectronic devices may be manifested as single chip devices or may be contained in multi-chip modules (MCMs). The semiconductor chip may further include inorganic and/or organic materials that are not semiconductor, for example, insulators such as inorganic dielectric materials or polymers, or conductors such as metals.

For the purposes of this disclosure, the term “high voltage” refers to operating potentials greater than 450 volts, and “low voltage” refers to operating potentials less than 100 volts. For example, a high voltage portion of the isolation device may operate at 450 volts to 1200 volts, while a low voltage portion of the isolation device may operate at 1.5 volts to 30 volts.

It is noted that terms such as top, bottom, front, back, over, above, under, and below may be used in this disclosure. These terms should not be construed as limiting the position or orientation of a structure or element, but should be used to provide spatial relationship between structures or elements. Similarly, words such as “inward” and “outward” would refer to directions toward and away from, respectively, the geometric center of a device or area and designated parts thereof.

For the purposes of this disclosure, the term “lateral” refers to a direction parallel to a plane of the instant top surface of the microelectronic device the term “vertical” is understood to refer to a direction perpendicular to the plane of the instant top surface of the microelectronic device.

For the purposes of this disclosure, the term “conductive” is to be interpreted as “electrically conductive.” The term “conductive” refers to materials and structures capable of supporting a steady electrical current, that is, direct current (DC).

For the purposes of this disclosure, the “dielectric constant” of a material refers to a ratio of the material's (absolute) permittivity to the vacuum permittivity, at a frequency below 1 hertz (Hz). The vacuum permittivity has a value of approximately 8.85×10⁻¹² farads/meter (F/m).

For the purposes of this disclosure, unless otherwise noted, the term high stress silicon dioxide refers to a silicon dioxide film with a stress of between −150 MPa and −80 MPa and the term low stress silicon dioxide refers to a silicon dioxide film with a stress of between −60 MPa and −10 MPa. Additionally, a negative stress implies a compressive stress and a positive stress implies a tensile stress.

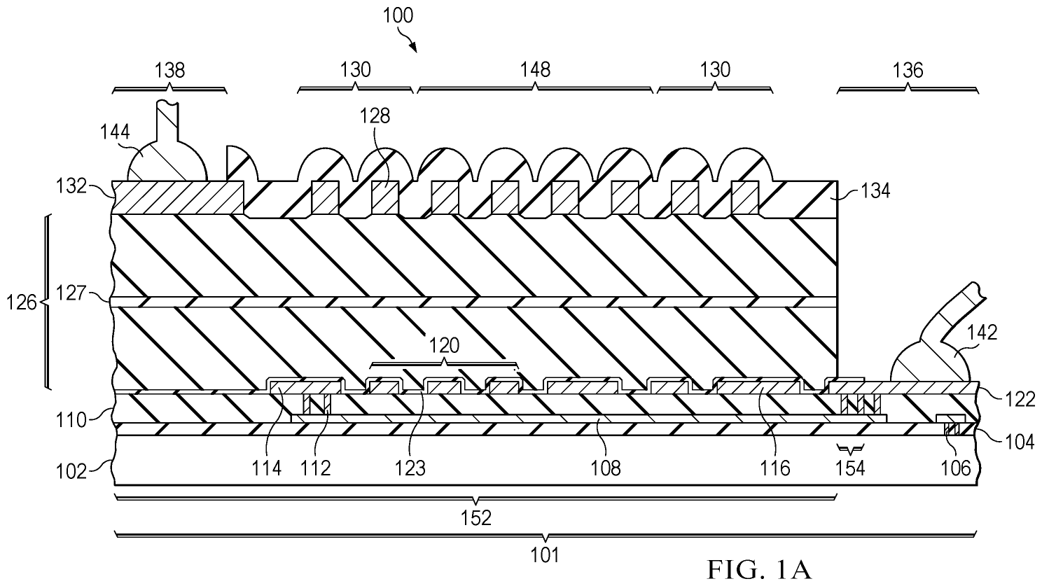

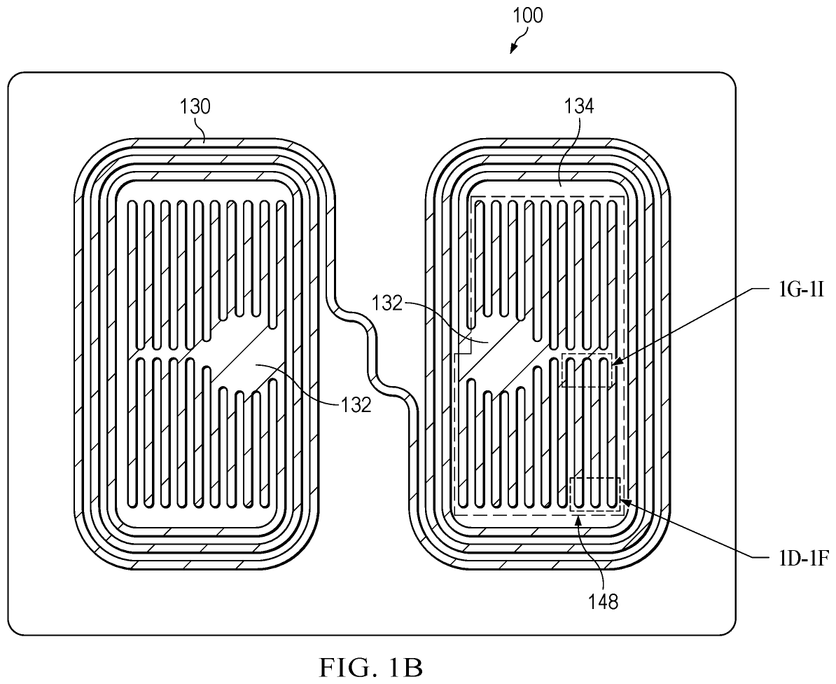

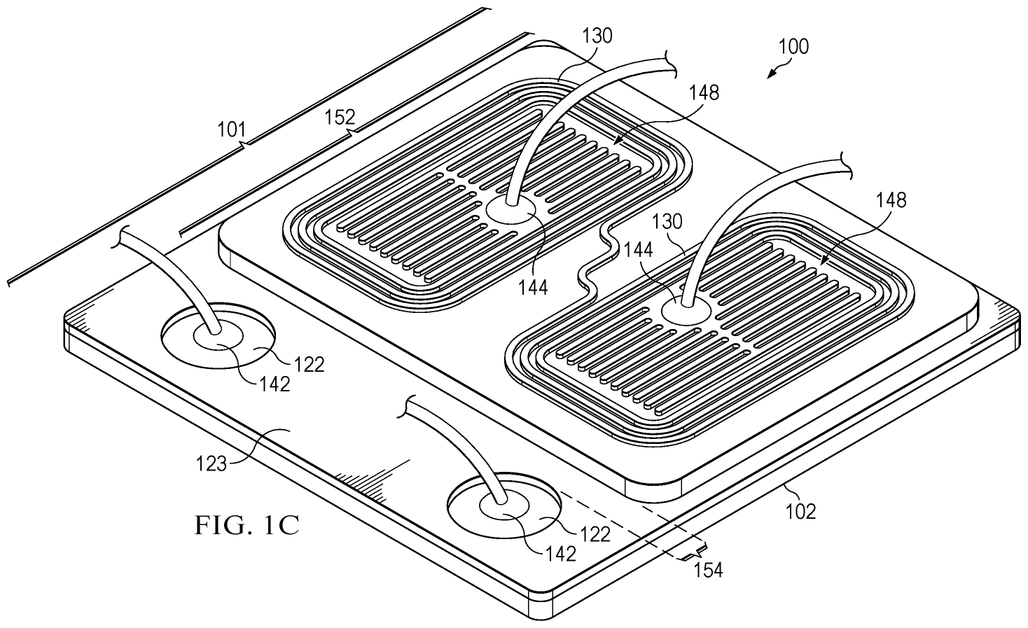

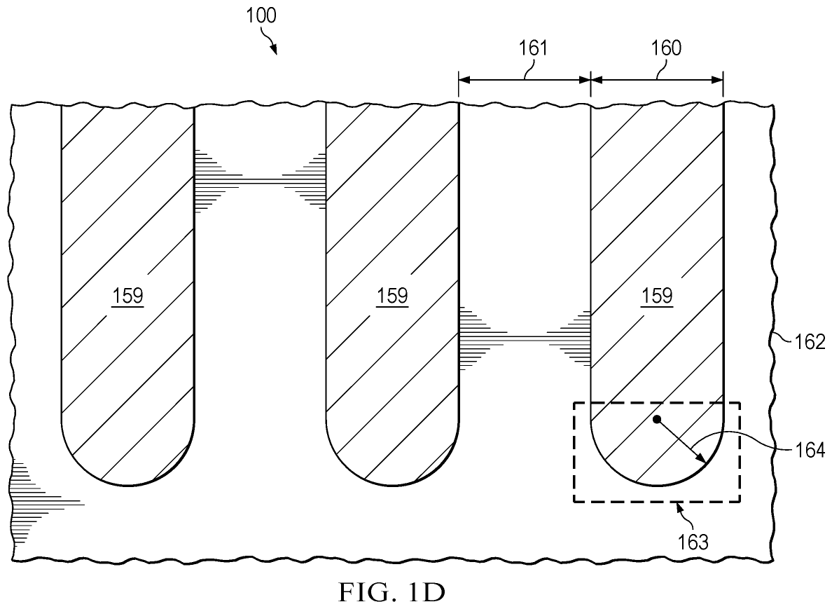

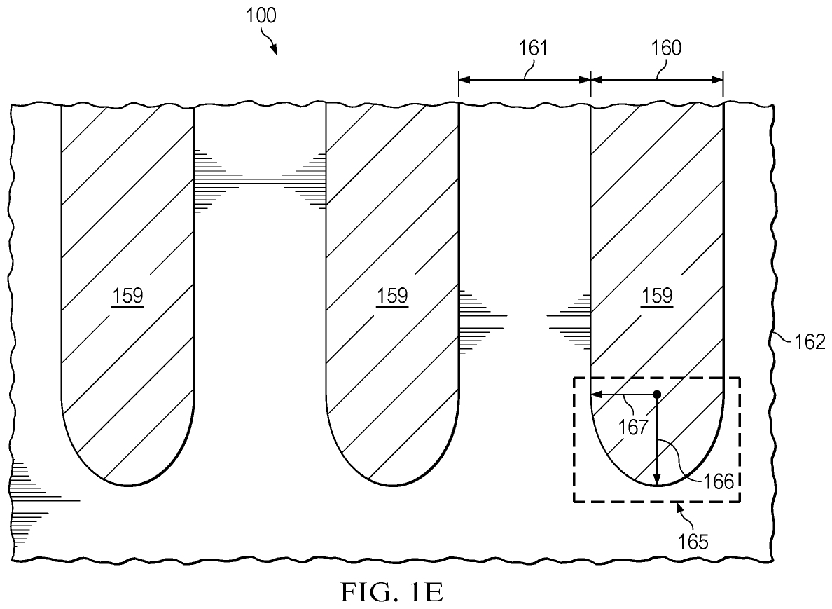

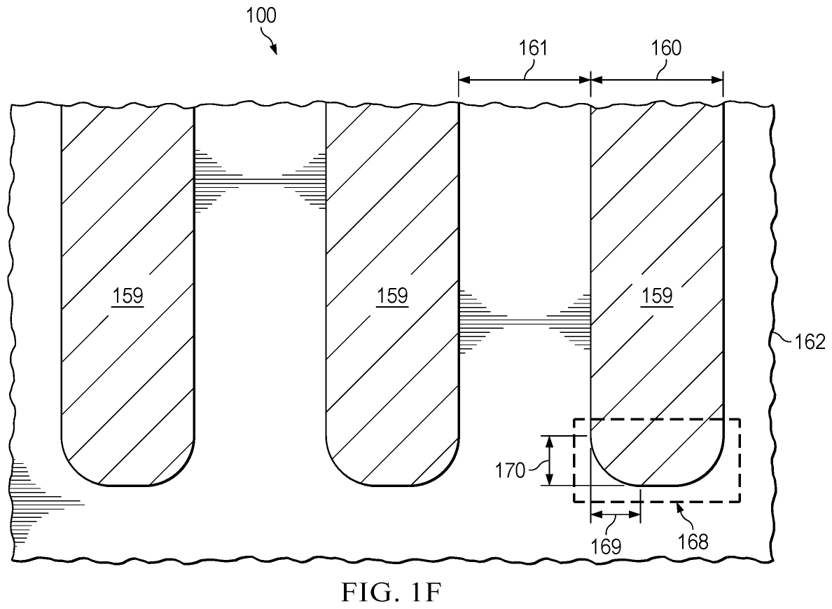

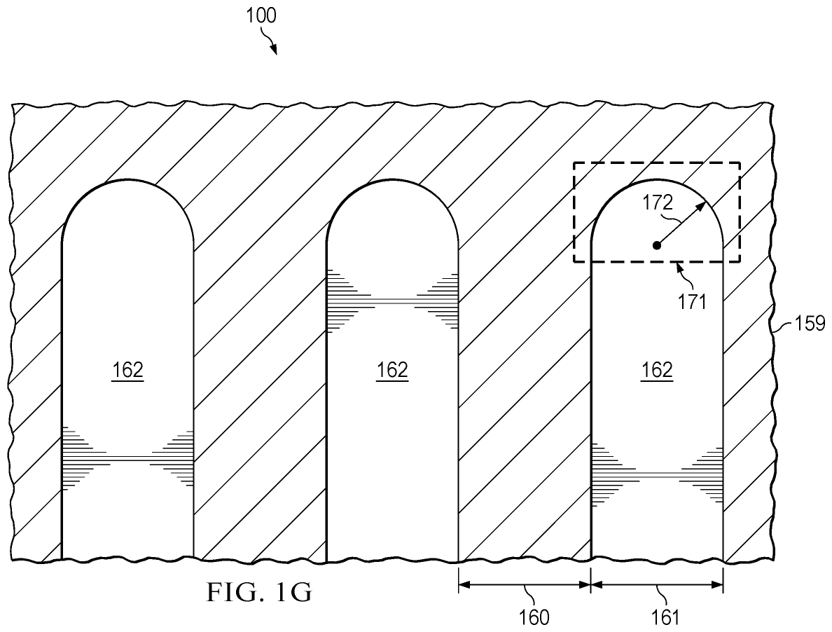

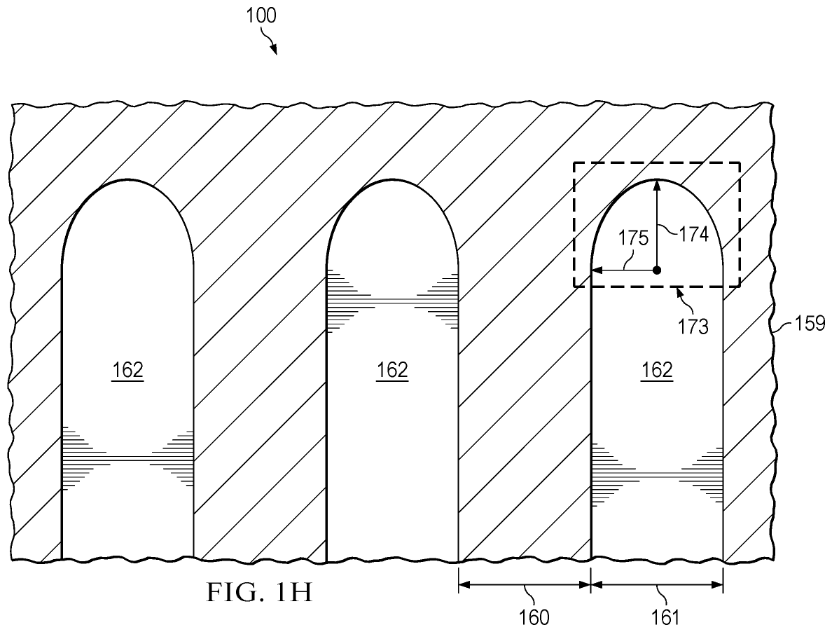

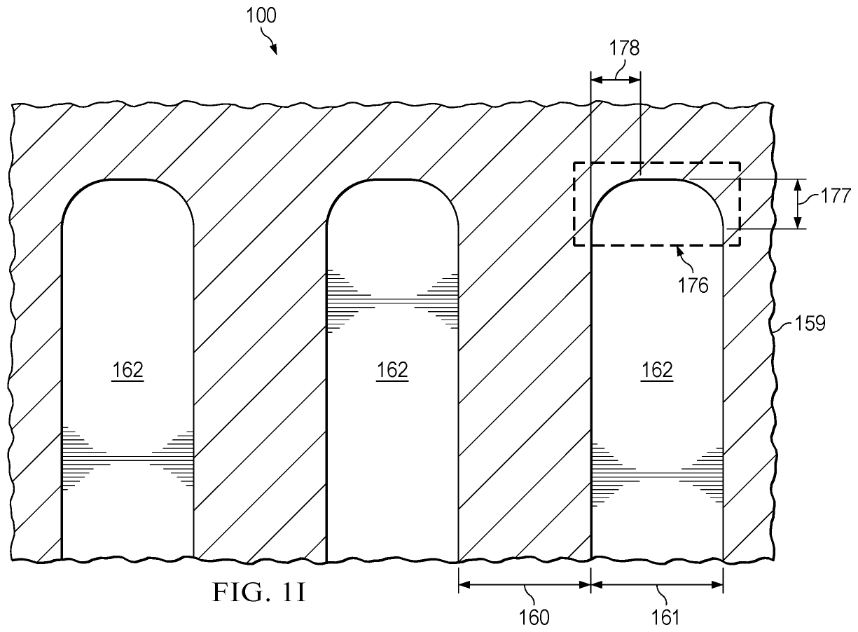

FIG. 1A is a cross section of an example microelectronic device 100 including a portion of an isolation device 101. The microelectronic device 100 may be implemented as part of a multi-chip array to provide galvanic isolation between a high voltage component and a low voltage component. The isolation device 101 of this example is a transformer, but could include a capacitor, a magnetic isolator, an optical isolator, a thermal isolator, or other elements which require galvanic isolation between high voltage and low voltage elements. The microelectronic device 100 is formed on a substrate 102, which may be part of a semiconductor wafer and may contain additional microelectronic devices. The substrate 102 includes a semiconductor material. The semiconductor material may include crystalline silicon, or may include another semiconductor material, such as silicon germanium, silicon carbide, gallium nitride, or gallium arsenide, by way of example.

A pre-metal dielectric (PMD) layer 104 is formed over the substrate 102. The PMD layer 104 includes one or more dielectric layers of silicon dioxide, phosphosilicate glass (PSG), fluorosilicate glass (FSG), borophosphosilicate glass (BPSG), organosilicate glass (OSG), low-k dielectric material, silicon nitride, silicon oxynitride, silicon carbide, silicon carbide nitride, or other dielectric materials. The PMD layer 104 may be formed by one or more dielectric deposition processes, such as a low-pressure chemical vapor deposition (LPCVD) process, a plasma enhanced chemical vapor deposition (PECVD) process, a high aspect ratio process (HARP) using ozone and tetraethyl orthosilicate (TEOS), high density plasma deposition (HDP), or an atmospheric pressure chemical vapor deposition (APCVD) process.

Contacts 106 of the first level interconnects 108 are formed through the PMD layer 104 to make electrical connections to the substrate 102. The contacts 106 are electrically conductive, and may include tungsten on a titanium adhesion layer and a titanium nitride liner. The contacts 106 may be formed by etching contact holes through the PMD layer 104, and forming the titanium adhesion layer by a physical vapor deposition (PVD) process. The titanium nitride liner may be formed on the titanium adhesion layer by an atomic layer deposition (ALD) process or chemical vapor deposition (CVD) process. The tungsten may be formed on the titanium nitride liner by a metalorganic chemical vapor deposition (MOCVD) process using tungsten hexafluoride reduced by silane and hydrogen. Tungsten, titanium nitride, and titanium on a top surface of the PMD layer 104, outside of the contacts 106, may be removed by a tungsten etch back process, a tungsten chemical mechanical polish (CMP) process, or both.

By way of example, the metallization of the isolation device 101 is described for an etched aluminum-based interconnect system. The isolation device 101 may also be formed using a copper-based interconnect system. First level interconnects 108 are formed on the PMD layer 104, making electrical connections to the contacts 106. The first level interconnects 108 are electrically conductive. The first level interconnects 108 may have an etched aluminum structure, and may include an adhesion layer, not specifically shown, of titanium nitride or titanium tungsten, on the PMD layer 104, an aluminum layer, not specifically shown, with a few atomic percent of silicon, titanium, or copper, on the adhesion layer, and an anti-reflection layer, not specifically shown, of titanium nitride on the aluminum layer. An etch mask, not specifically shown, is formed followed by a reactive ion etch (RIE) process to etch the anti-reflection layer, the aluminum layer, and the adhesion layer where exposed by the etch mask, and subsequently removing the etch mask to form the first level interconnects 108.

A first interlevel dielectric (ILD) layer 110 which may include a single layer of dielectric or multiple dielectric layers may be formed on the first level interconnects 108. After the formation of the first ILD layer 110, first level vias 112 are formed in the first ILD layer 110, making electrical connection to the first level interconnects 108. The first level vias 112 may be formed by etching via holes through the first ILD layer 110, and forming a titanium adhesion layer by a physical vapor deposition (PVD) process. A titanium nitride liner may be formed on the titanium adhesion layer by an atomic layer deposition (ALD) process or chemical vapor deposition (CVD) process. Tungsten may be formed on the titanium nitride liner by a metalorganic chemical vapor deposition (MOCVD) process using tungsten hexafluoride reduced by silane and hydrogen. Tungsten, titanium nitride, and titanium on a top surface of the first level vias 112, outside of the via holes may be removed by a tungsten etch back process, a tungsten chemical mechanical polish (CMP) process, or both.

Second level interconnects 114 are formed on the first ILD layer 110 making electrical contact with the first level vias 112. The second level interconnects 114 are electrically conductive. The second level interconnects 114 may have an etched aluminum structure, and may include an adhesion layer, not specifically shown, of titanium nitride or titanium tungsten, on the first ILD layer 110, an aluminum layer, not specifically shown, with a few atomic percent of silicon, titanium, or copper, on the adhesion layer, and an anti-reflection layer, not specifically shown, of titanium nitride on the aluminum layer. A second interconnects etch mask (not specifically shown), is formed followed by a reactive ion etch (RIE) process to etch the anti-reflection layer, the aluminum layer, and the adhesion layer where exposed by the etch mask, and subsequently removing the etch mask to form the second level interconnects 114. In this example, a lower metal coil 120 of the isolation device 101 may be formed in the second level interconnects 114 but may be formed at other levels. A ground ring 116 (grounding outside of the plane of the cross section of FIG. 1A) for the isolation device 101 is also formed in the second level interconnects 114. A lower bond pad 122 may also be formed in the second level interconnects 114.

A dielectric stack 126 is deposited on the second level interconnects 114 which forms subsequently forms a plateau 152 of the isolation device 101 between the lower metal coil 120 and the upper metal coil 130. The dielectric layers composing the dielectric stack 126 may singly or in combination be composed of low stress silicon dioxide, high stress silicon dioxide, high density plasma (HDP) silicon dioxide, silicon oxynitride, and silicon nitride. The low stress silicon dioxide may have a stress between −60 MPa and −10 MPa. The high stress silicon dioxide may have a stress between −150 MPa and −80 MPa. The HDP silicon dioxide may have a stress between −120 MPa and −90 MPa. The silicon oxynitride may have a stress between −120 MP and 0 MPa. The silicon nitride may have a stress between −1 GPa and −100 MPa. The dielectric stack may also contain an etch stop layer 123 of silicon nitride or silicon oxynitride over the lower metal coil 120 and the lower bond pad 122. The dielectric stack may also contain an etch stop layer 127 of silicon nitride or silicon oxynitride within the dielectric stack.

Top metal interconnects 128 are formed on the dielectric stack 126. The top metal interconnects 128 may have an etched aluminum structure, and may include an adhesion layer, not specifically shown, of titanium nitride or titanium tungsten, upper, an aluminum layer, not specifically shown, with a few atomic percent of silicon, titanium, or copper, on the adhesion layer, and an anti-reflection layer, not specifically shown, of titanium nitride on the aluminum layer. A top metal interconnects photolithography mask (not specifically shown) is formed followed by a reactive ion etch (RIE) process to etch the anti-reflection layer, the aluminum layer, and the adhesion layer where exposed by the etch mask. The RIE used to etch the top metal interconnects may remove up to 200 nm of the dielectric stack 126 in areas exposed to the RIE. Features of the top metal interconnects 128 shown include the upper metal coil 130 and the top metal bond pad 132 and a filler metal layer 148 which is electrically in contact with the upper metal coil 130. The top metal interconnects 128 may also be formed using a copper damascene process.

The upper metal coil 130 has a filler metal layer 148 which provides a means to enhance the overall metal density for the top metal layer. For aluminum-based technologies, minimum metal density rules are often implemented. Minimum metal density rules are necessary to have enough resist present on the wafer during the metal etch process. If sufficient resist is not present during the metal etch process, insufficient polymer sidewall is formed during the metal etch process which can result in metal sidewall pitting and undercutting of isolated narrow metal geometries.

A protective overcoat 134 is formed over the top metal interconnects 128. The protective overcoat is formed by a deposition of silicon oxynitride, silicon nitride, or a combination thereof. A series of etch steps (not specifically shown), remove the protective overcoat 134 in the upper bond pad region 138 to expose the top metal bond pad 132 as well as remove the protective overcoat and the dielectric stack in the lower bond pad region 136 to expose the lower bond pad 122. The etch stop layer 123, may remain in areas outside the lower bond pad region 136 creating a plateau to bond pad space 154. An upper ball bond 144 to the top metal bond pad 132, and a lower ball bond 142 to the lower bond pad 122 are shown.

Referring to FIG. 1B, a top down view of the upper metal coil 130 and the filler metal layer 148 are shown. A top metal bond pad 132 is also shown. The upper metal coil 130, filler metal layer 148, and top metal bond pad 132 are all in electrical contact with each other. A filler metal layer 148 may be required to meet the fabrication requirements in both aluminum based and copper based interconnect technologies. In an aluminum based interconnect technology system, the filler metal layer 148 may be needed with an upper metal coil 130 if the metal density of the upper metal coil 130 near the upper metal coil 130 does not meet the overall metal density requirements of the associated fabrication technology. If the metal density of the upper metal coil 130 layer near the upper metal coil 130 is too low in a subtractive aluminum etch process, the resulting sidewall of the etched aluminum may be pitted or undercut due to lack of available polymer from the photoresist to passivate the etch sidewalls. The addition of a filler metal layer 148 increases the metal density of the top metal interconnects (not specifically shown) to meet the required minimum metal density of the process technology. In a copper damascene process, the filler metal layer 148 inhibits dishing from areas of high metal density compared to low metal density. The filler metal layer 148 assists in providing more uniform metal density across the microelectronic device 100 which results in more uniform profiles of the resulting metal profiles after copper CMP.

For the purposes of this disclosure, metal features not electrically connected to the upper metal coil 130 are defined as near the upper metal coil 130 if they are within 5 microns of the upper metal coil 130. For the purposes of this disclosure low metal density is defined as a metal density for a 50 micron by 50 micron or larger region of the top metal interconnects 128, as shown in FIG. 1A, with a metal density of less than 25 percent.

The end regions shown in FIG. 1D-1I of the filler metal layer 148 filler metal tine 159 may impact the electric field reliability of the filler metal layer 148 when the filler metal layer 148 is within an upper metal coil 130 of an isolation device 101. To minimize electric field effects, it is advantageous to round the external corners and internal corners of the filler metal layer 148 filler metal tine 159. End regions in microelectronic circuits generally have some rounding at the line edge due to the effects of photolithography and etching of the line end features. However, for geometries which are more than one and a half times the wavelength of the photolithography radiation, this rounding may be limited, and thus a rounded tine termination in the design database of both the interior tine end and the exterior tine end of the filler metal tine 159 features is necessary to minimize electric field effects of the filler metal layer 148 on the upper metal coil 130.

FIG. 1C shows a perspective view of an example microelectronic device 100 with an isolation device 101 and a filler metal layer 148 within the upper metal coil 130. The upper metal coil 130 and filler metal layer 148 are on the plateau 152. The filler metal layer 148 provides increased metal density for fabrication processing. The protective overcoat 134 of FIG. 1A is removed for clarity. Other elements shown in the perspective view include the substrate 102, the lower bond pad 122, the lower ball bond 142, an etch stop layer 123, the plateau to bond pad space 154, the upper ball bond 144, and etch stop layer 123.

Referring to FIG. 1D, a detailed view of a filler metal tine 159 with a semicircular exterior tine termination 163 is shown. The filler metal tine 159 has a metal tine width 160 and a metal tine space 161. The underlying plateau dielectric 162 can be seen in the metal tine space 161 region. The semicircular exterior tine termination 163 has a semicircular tine termination radius 164. To minimize electric field effects of the filler metal tine 159, it is advantageous for the filler metal tine 159 to have a semicircular tine termination 163 compared to a termination with sharp corners (not specifically shown).

Referring to FIG. 1E, a detailed view of a filler metal tine 159 with an elliptical exterior tine termination 165 is shown. The filler metal tine 159 has a metal tine width 160 and a metal tine space 161. The underlying plateau dielectric 162 can be seen in the metal tine space 161 region. The elliptical tine termination 163 has an elliptical tine termination length 166 and an elliptical tine termination radius 167. To minimize electric field effects of the filler metal tine 159, it is advantageous for the filler metal tine 159 to have an elliptical exterior tine termination 165 compared to a termination with sharp corners (not specifically shown).

Referring to FIG. 1F, a detailed view of a filler metal tine 159 with a corner rounded exterior tine termination 168 is shown. The filler metal tine 159 has a metal tine width 160 and a metal tine space 161. The underlying plateau dielectric 162 can be seen in the metal tine space 161 region. The corner rounded tine termination 168 has a corner rounded termination length 169 and a corner rounded termination radius 170. The corner rounded termination radius 170 is greater than 20 percent of the width of the filler metal tine 159. To minimize electric field effects of the filler metal tine 159, it is advantageous for the filler metal tine 159 to have a corner rounded exterior tine termination 168 compared to a termination with sharp corners (not specifically shown).

FIG. 1G is a detailed view of a semicircular interior tine termination region 171 of a filler metal tine 159. To minimize electric fields, it is advantageous to form a semicircular interior tine termination region 171 of the filler metal tine 159. The semicircular interior tine termination region 171 shows a metal tine width 160, a metal tine space 161. In the region of the metal tine space 161, the underlying plateau dielectric 162 is shown. The semicircular interior tine termination region 171 contains a semicircular tine end radius 172.

FIG. 1H is a detailed view of an elliptical interior tine termination region 173 of a filler metal tine 159. To minimize electric fields, it is advantageous to form an elliptical interior tine termination region 173 of the filler metal tine 159. The elliptical interior tine termination region 173 shows a metal tine width 160, a metal tine space 161. In the region of the metal tine space 161, the underlying plateau dielectric 162 is shown. The elliptical interior tine termination region 173 contains an interior elliptical tine end length 174, and an interior elliptical tine edge radius 175.

FIG. 1I is a detailed view of an interior corner rounded tine termination region 176 of a filler metal tine 159. To minimize electric fields, it is advantageous to form an interior corner rounded tine termination region 176 of the filler metal tine 159 of the filler metal layer 148. The interior corner rounded tine termination region 176 shows a metal tine width 160, a metal tine space 161. In the region of the metal tine space 161, the underlying plateau dielectric 162 is shown. The interior corner rounded tine termination region 176 contains an interior corner rounded tine end arc length 177, and an interior corner rounded termination radius 178. The interior corner rounded termination radius 178 is greater than 20 percent of the width of the filler metal tine 159.

What is claimed is:

1. A microelectronic device, comprising:
a substrate;
an isolation device including;
a lower isolation element over the substrate;
a dielectric stack over the lower isolation element; and
an upper isolation element over the dielectric stack;
an upper bond pad over the dielectric stack, in electrical contact with the upper isolation element;
a filler metal layer over the dielectric stack, in electrical contact with the upper isolation element; and
a lower bond pad in electrical connection with the lower isolation element.

2. The microelectronic device of claim 1, wherein the filler metal layer contains a filler metal tine with a rounded tine termination.

3. The microelectronic device of claim 2, wherein the rounded tine termination is semicircular in geometry.

4. The microelectronic device of claim 2, wherein the rounded tine termination is elliptical in geometry.

5. The microelectronic device of claim 2, wherein the rounded tine termination contains rounded corners which are greater than 20 percent of a width of the filler metal tine.

6. The microelectronic device of claim 2, wherein the rounded tine termination is an interior tine termination.

7. The microelectronic device of claim 2, wherein the rounded tine termination is an exterior tine termination.

8. The microelectronic device of claim 2, wherein the rounded tine termination is an exterior tine termination and further comprising a rounded interior tine termination.

9. The microelectronic device of claim 1 wherein the dielectric stack contains one or more layers of a low stress silicon dioxide.

10. The microelectronic device of claim 1 wherein the upper isolation element and filler metal layer are of an etched aluminum-based interconnect system.

11. A method of forming a microelectronic device, comprising:
forming a lower isolation element of an isolation device over a substrate;
forming a dielectric stack of the isolation device over the lower isolation element;
concurrently forming an upper isolation element and a filler metal layer of an isolation device, over the dielectric stack, wherein the filler metal layer is in electrical contact with the upper isolation element;
forming an upper bond pad over the dielectric stack, in electrical contact with upper isolation element; and
forming a lower bond pad in electrical connection with the lower isolation element.

12. The method of claim 11, wherein the filler metal layer contains a filler metal tine with a rounded tine termination.

13. The method of claim 12, wherein the rounded tine termination is semicircular in geometry.

14. The method of claim 12, wherein the rounded tine termination is elliptical in geometry.

15. The method of claim 12, wherein the rounded tine termination contains rounded corners which are greater than 20 percent of a width of the filler metal tine.

16. The method of claim 12, wherein the rounded tine termination is an interior tine termination.

17. The method of claim 12, wherein the rounded tine termination is an exterior tine termination.

18. The method of claim 12, wherein the rounded tine termination is an exterior tine termination and further comprising a rounded interior tine termination.

19. The method of claim 11 wherein the dielectric stack contains one or more layers of a low stress silicon dioxide.

20. The method of claim 11 wherein concurrently forming the upper isolation element and the filler metal layer includes:
forming an adhesion layer on the dielectric stack;
forming an aluminum layer on the adhesion layer;
forming an anti-reflective layer of titanium nitride on the aluminum layer;
forming an etch mask on the anti-reflective layer;
etching the anti-reflective layer, the aluminum layer, and the adhesion layer where exposed by the etch mask using a reactive ion etch process; and
removing the etch mask.
